(19) United States
(12) Patent Application Publication
(10) Pub. No.: US 2014/0027838 A1
(43) Pub. Date: Jan. 30, 2014

(54) SEMICONDUCTOR DEVICE AND METHOD FOR MANUFACTURING THE SAME

(71) Applicant: KABUSHIKI KAISHA TOSHIBA, Minato-ku (JP)

(72) Inventors: Nozomi Kido, Mie-ken (JP); Yosuke Komori, Mie-ken (JP)

(73) Assignee: KABUSHIKI KAISHA TOSHIBA, Minato-ku (JP)

(21) Appl. No.: 13/950,564

(22) Filed: Jul. 25, 2013

(30) Foreign Application Priority Data
Jul. 26, 2012 (JP) 2012-166071

(51) Int. Cl. H01L 27/088; H01L 21/8232

(52) U.S. Cl. CPC H01L 27/088; H01L 21/8232
USPC 257/329; 438/269

(57) ABSTRACT

According to one embodiment, the stair array includes a deep portion, one stair, and a plurality of stairs. The one stair is provided next to the deepest portion in the first direction and has a level difference of one step with the deepest portion. Each of the stairs has a level difference of a plurality of steps with a stair next in the first direction.

### CROSS-REFERENCE TO RELATED APPLICATION

This application is based upon and claims the benefit of priority from Japanese Patent Application No. 2012-166071, filed on Jul. 26, 2012; the entire contents of which are incorporated herein by reference.

### FIELD

Embodiments described herein relate generally to a semiconductor device and a method for manufacturing the same.

### BACKGROUND

A memory device of a three-dimensional structure is proposed in which a memory hole is formed in a stacked body in which an electrode layer functioning as the control gate of a memory cell and an insulating layer are alternately stacked in plural, and a silicon body serving as a channel is provided on the side wall of the memory hole via a charge storage film.

As a structure for connecting each of the plurality of stacked electrode layers to another interconnection, a structure in which the plurality of electrode layers are processed in a staircase configuration is proposed.

### BRIEF DESCRIPTION OF THE DRAWINGS

FIG. 1 is a schematic plan view showing an arrangement relationship between a memory cell array and a staircase structure unit in a semiconductor device of an embodiment;

FIG. 2 is a schematic perspective view of the memory cell array in a semiconductor device of the embodiment;

FIG. 3 is an enlarged cross-sectional view of a part in FIG. 2;

FIG. 4A to FIG. 8D are schematic cross-sectional views showing a method for manufacturing a staircase structure in a first embodiment;

FIG. 9A is a schematic plan view of a staircase structure unit in a second embodiment, and FIG. 9B is a schematic perspective view of the staircase structure in the second embodiment;

FIG. 10 is a schematic cross-sectional view of the staircase structure in the second embodiment;

FIGS. 11A and 11B are schematic perspective views showing a method for manufacturing the staircase structure in the second embodiment;

FIG. 12 is a schematic plan view of a staircase structure unit in a third embodiment;

FIG. 13 is a cross-sectional view along line B-B′ in FIG. 12; and

FIGS. 14A and 14B are schematic cross-sectional views showing a method for manufacturing a staircase structure of a comparative example.

### DETAILED DESCRIPTION

According to one embodiment, a semiconductor device includes a stacked body and a plurality of vias. The stacked body includes a plurality of conductive layers and a plurality of insulating layers each provided between the conductive layers. The stacked body includes a staircase structure unit including a stair array including stairs of the conductive layers aligned in a line in a first direction in a staicase configuration. The vias are provided individually above the stairs and individually reach the conductive layers. The stair array includes a deep portion, one stair, and a plurality of stairs. The one stair is provided next to the deepest portion in the first direction and has a level difference of one step to the deepest portion. Each of the stairs has a level difference of a plurality of steps to a stair next in the first direction.

Various embodiments will be described hereinafter with reference to the accompanying drawings.

In the drawings, identical components are marked with the same reference numerals.

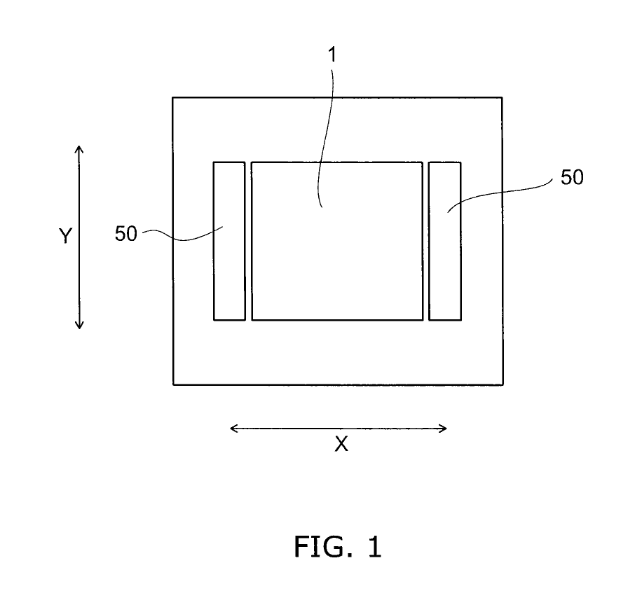

FIG. 1 is a schematic plan view showing an arrangement relationship between a memory cell array 1 and a staircase structure unit 50 in a semiconductor device of an embodiment. FIG. 1 corresponds to the region of one chip.

The memory cell array 1 is formed in the center of the chip. The staircase structure unit 50 is formed on the outside in a first direction (the X direction) of the memory cell array 1. A circuit that drives the memory cell array 1 etc. are formed in a region around the memory cell array 1 and the staircase structure unit 50.

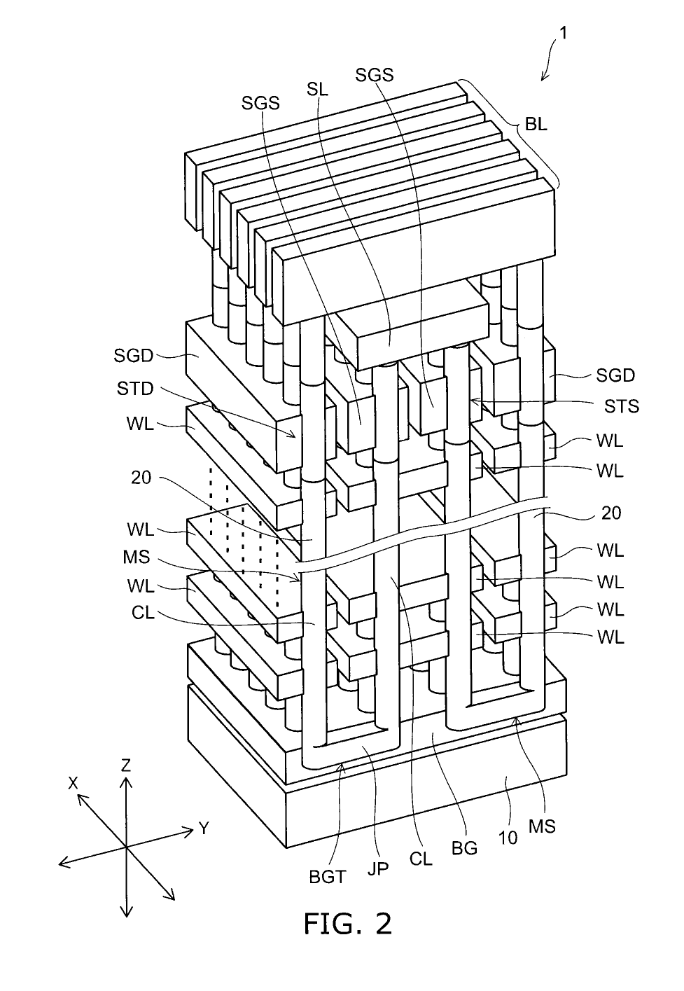

FIG. 2 is a schematic perspective view of the memory cell array 1. In FIG. 2, the illustration of the insulating portions is omitted for easier viewing of the drawing.

In FIG. 2, an XYZ orthogonal coordinate system is introduced. Two directions parallel to the major surface of a substrate 10 and orthogonal to each other are defined as the X direction (the first direction) and the Y direction (a second direction), and the direction orthogonal to both of the X direction and the Y direction is defined as the Z direction (a third direction or the stacking direction).

The memory cell array 1 includes a plurality of memory strings MS. One memory string MS is formed in a U-shaped configuration including a pair of columnar portions CL and a joining portion JP joining the lower ends of the pair of columnar portions CL.

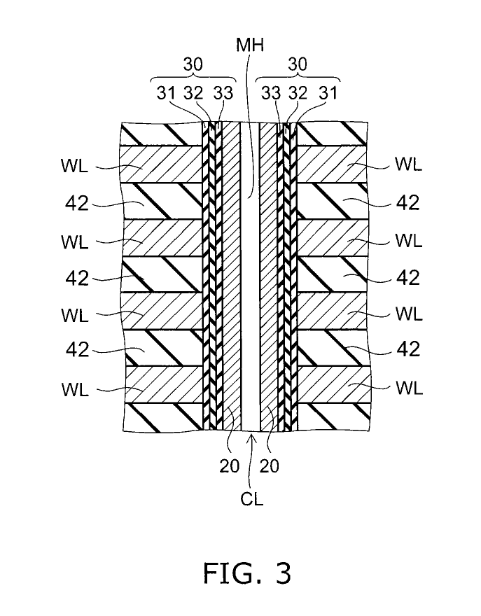

FIG. 3 shows an enlarged cross-sectional view of the columnar portion CL of the memory string MS.

As shown in FIG. 2, a back gate BG is provided on the substrate 10. The back gate BG is a conductive layer, and a silicon layer doped with an impurity, for example, may be used.

A plurality of insulating layers 42 (shown in FIG. 3) and a plurality of electrode layers WL are alternately stacked on the back gate BG. The insulating layer 42 is provided between an electrode layer WL and an electrode layer WL.

The electrode layer WL is a conductive layer, and a silicon layer doped with an impurity, for example, may be used. For the insulating layer 42, for example, an insulating material containing silicon oxide may be used.

A drain-side select gate SGD is provided in an end portion of one of the pair of columnar portions CL of the U-shaped memory string MS, and a source-side select gate SGS is provided in an end portion of the other of the pair of columnar portions CL. The drain-side select gate SGD and the source-side select gate SGS are provided on the uppermost electrode layer WL. The drain-side select gate SGD and the source-side select gate SGS are a conductive layer, and a silicon layer doped with an impurity, for example, may be used.

The drain-side select gate SGD and the source-side select gate SGS are divided in the Y direction. Also the electrode layer WL stacked under the drain-side select gate SGD and the electrode layer WL stacked under the source-side select gate SGS are divided in the Y direction.

A source line SL is provided on the source-side select gate SGS. For the source line SL, for example, a metal layer may be used.

Bit lines BL that are a plurality of metal interconnections are provided on the drain-side select gate SGD and the source line SL. Each bit line BL extends in the Y direction.

The memory string MS includes a channel body 20 (shown in FIG. 3) provided in a U-shaped memory hole MH formed in the stacked body including the back gate BG, the plurality of electrode layers WL, the plurality of insulating layers 42, the drain-side select gate SGD, and the source-side select gate SGS.

The channel body 20 is provided in the U-shaped memory hole MH via a memory film 30. For the channel body 20, for example, a silicon film may be used. As shown in FIG. 3, the memory film 30 is provided between the inner wall (the side wall and the bottom wall) of the memory hole MH and the channel body 20.

Although FIG. 3 illustrates a structure in which the channel body 20 is provided such that a hollow portion remains on the central axis side of the memory hole MH, the entire space in the memory hole MH may be filled up with the channel body 20, or a structure in which an insulator is buried in the hollow portion on the inside of the channel body 20 is possible.

The memory film 30 includes a block film 31 as a first insulating film, a charge storage film 32, and a tunnel film 33 as a second insulating film. The block film 31, the charge storage film 32, and the tunnel film 33 are provided in this order from the electrode layer WL side between each electrode layer WL and the channel body 20. The block film 31 is in contact with the electrode layer WL, the tunnel film 33 is in contact with the channel body 20, and the charge storage film 32 is provided between the block film 31 and the tunnel film 33.

The channel body 20 functions as a channel in a memory cell, the electrode layer WL functions as a control gate, and the charge storage film 32 functions as a data memory layer that stores a charge injected from the channel body 20. That is, a memory cell with a structure in which the control gate surrounds the periphery of the channel is formed at the intersection between the channel body 20 and each electrode layer WL.

The semiconductor device of the embodiment is a nonvolatile semiconductor memory device that can perform the erasing and writing of data electrically in a free manner and can retain the memory content even when the power is turned off.

The memory cell is, for example, a charge trap memory cell. The charge storage film 32 includes a large number of trap sites that trap a charge, and a silicon nitride film, for example, may be used.

For the tunnel film 33, for example, a silicon oxide film may be used, and the tunnel film 33 forms a potential barrier when a charge is injected from the channel body 20 into the charge storage film 32 or when the charge stored in the charge storage film 32 is diffused to the channel body 20.

For the block film 31, for example, a silicon oxide film may be used, and the block film 31 prevents the charge stored in the charge storage film 32 from diffusing to the electrode layer WL.

The drain-side select gate SGD, the channel body 20, and the memory film 30 between them constitute a drain-side select transistor STD. Above the drain-side select gate SGD, the channel body 20 is connected to the bit line BL.

The source-side select gate SGS, the channel body 20, and the memory film 30 between them constitute a source-side select transistor STS. Above the source-side select gate SGS, the channel body 20 is connected to the source line SL.

The back gate BG, and the channel body 20 and the memory film 30 provided in the back gate BG constitute a back gate transistor BGT.

The memory cell using each electrode layer WL as the control gate is provided in plural between the drain-side select transistor STD and the back gate transistor BGT. Similarly, the memory cell using each electrode layer WL as the control gate is provided in plural also between the back gate transistor BGT and the source-side select transistor STS.

The plurality of memory cells, the drain-side select transistor STD, the back gate transistor BGT, and the source-side select transistor STS are connected in series via the channel body 20, and constitute one U-shaped memory string MS. The memory string MS is arranged in plural in the X direction and the Y direction; thus, a plurality of memory cells are provided three-dimensionally in the X direction, the Y direction, and the Z direction.

Each of the plurality of conductive layers including the back gate BG and the electrode layers WL in the memory cell array 1 is connected to a circuit interconnection via the staircase structure unit 50.

### First Embodiment

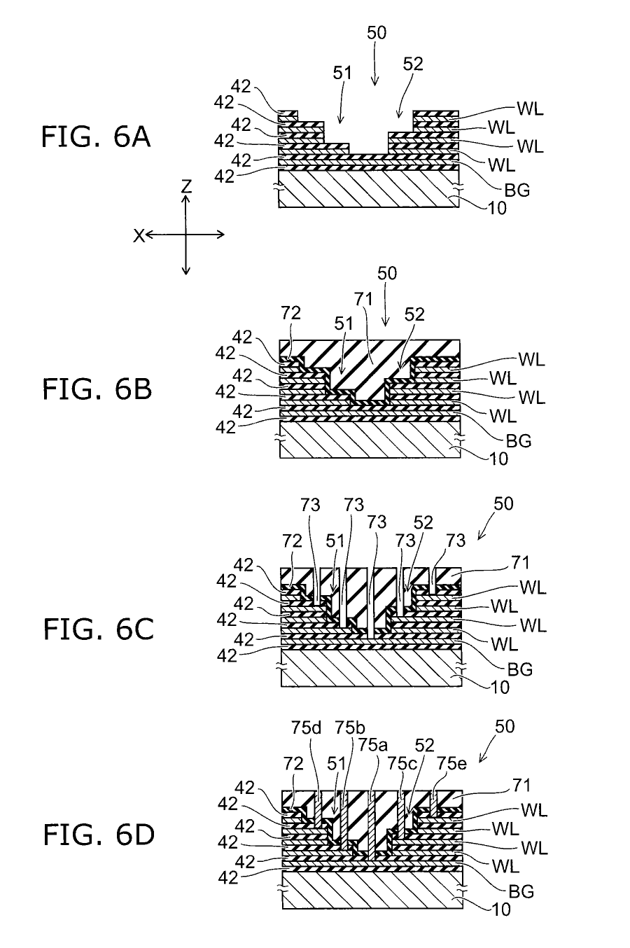

FIG. 6D is a schematic cross-sectional view of the staircase structure unit 50 of a first embodiment. Although FIG. 6D shows five conductive layers including the back gate BG and four electrode layers WL, for example, the number of conductive layers is not limited thereto.

The stacked body including the back gate BG, the plurality of insulating layers 42, and the plurality of electrode layers WL is provided also in a region on the outside in the X direction of the central region of the chip in which the memory cell array 1 is formed. The staircase structure unit 50 is provided in the stacked body in that region.

The back gate BG is provided on the substrate 10 via the insulating layer 42. The insulating layer 42 and the electrode layer WL are alternately stacked in plural on the back gate BG. The plurality of electrode layers WL and the plurality of insulating layers 42 are fashioned in a staircase configuration along the X direction.

The staircase structure unit 50 includes a stair array in which stairs of a plurality of conductive layers are aligned in a line in the X direction in a staircase configuration. Next to the back gate BG, which is the deepest portion of the stair array, in the X direction, a stair of the electrode layer (the lowest electrode layer excluding the back gate BG) WL having a level difference of one stair with the back gate BG is provided.

Next to the lowest electrode layer WL in the X direction, the third lowest electrode layer WL having a level difference of two stairs with the lowest electrode layer WL is provided.

Next to the back gate BG in the X direction, the second lowest electrode layer WL having a level difference of two stairs with the back gate BG is provided.

Next to the second lowest electrode layer WL in the X direction, the fourth lowest electrode layer WL having a level difference of two stairs with the second lowest electrode layer WL is provided.

On the staircase structure unit 50, an interlayer insulating film 71 is provided via an etching stop film 72. For the interlayer insulating film 71, for example, a silicon oxide film may be used. The etching stop film 72 is an insulating film made of a different material from the interlayer insulating film 71, and a silicon nitride film, for example, may be used.

A plurality of vias 75a to 75e are provided on the stairs in the staircase structure unit 50. Each of the plurality of vias 75a to 75e pierces the interlayer insulating film 71, the etching stop film 72, and the insulating layer 42 and reaches the uppermost conductive layer of each stair.

The via 75a reaches the deepest portion of the staircase structure unit 50, and is connected to the back gate BG. The via 75b is connected to the first electrode layer WL on the upper side from the back gate BG, which is the conductive layer of the deepest portion. The via 75c is connected to the second electrode layer WL on the upper side from the back gate BG. The via 75d is connected to the third electrode layer WL on the upper side from the back gate BG. The via 75e is connected to the fourth electrode layer WL on the upper side from the back gate BG.

A metal material may be used for the vias 75a to 75e. The vias 75a to 75e may include, for example, a barrier metal and an embedding metal. The barrier metal having the function of adhesion and metal diffusion prevention is formed on the inner wall of a via hole 73 shown in FIG. 6C, and the embedding metal excellent in burying condition is buried on the inside of the barrier metal. For example, titanium nitride may be used as the barrier metal, and tungsten may be used as the embedding metal.

The back gate BG of the staircase structure unit 50 is connected to the back gate BG of the memory cell array 1. Similarly, the electrode layer WL on each story of the staircase structure unit 50 is connected to the electrode layer WL on each story of the memory cell array 1.

Thus, the back gate BG and the electrode layers WL of the memory cell array 1 are connected to a not-shown interconnection provided on the stacked body via the vias 75a to 75e of the staircase structure unit 50. The interconnection is connected to a drive circuit formed on the surface of the substrate 10 via a not-shown via.

The staircase structure unit 50 has a first staircase region 51 and a second staircase region 52 provided to sandwich the deepest portion in the X direction. One of the first staircase region 51 and the second staircase region 52 is located on the memory cell array 1 side (the chip center side), and the other is located on the peripheral region side.

The structure illustrated in FIG. 6D includes, for example, three electrode layers (hereinafter may be referred to as intermediate electrode layers) WL between the back gate BG, which is the conductive layer of the deepest portion, and the uppermost electrode layer WL.

Of the vias 75b, 75c, and 75d reaching the intermediate electrode layers WL, the vias 75b and 75d reaching the intermediate electrode layers WL in odd positions (the first and the third) on the upper side from the back gate BG are provided in the first staircase region 51, and the via 75c reaching the intermediate electrode layer WL in an even position (the second) on the upper side from the back gate BG is provided in the second staircase region 52.

Although the via 75e reaching the uppermost electrode layer WL is provided in the second staircase region 52 in the example shown in FIG. 6D, the via 75e may reach the uppermost electrode layer WL in the first staircase region 51.

In the embodiment, the first staircase region 51 and the second staircase region 52 located to sandwich the deepest portion of the staircase structure unit 50 in the X direction do not include stairs of the intermediate electrode layer WL on the same story as each other. The vias 75a to 75e are provided to be allocated to both regions sandwiching the deepest portion of the staircase structure unit 50 in the X direction. The vias 75a to 75e are connected to conductive layers different from one another (the back gate BG or the electrode layers WL).

Therefore, no ineffective stair is produced in which no via is provided, and the stair structure unit 50 can be effectively used. Consequently, the increase in the area where the staircase structure unit 50 is provided can be suppressed, and eventually the chip area (chip size) can be reduced.

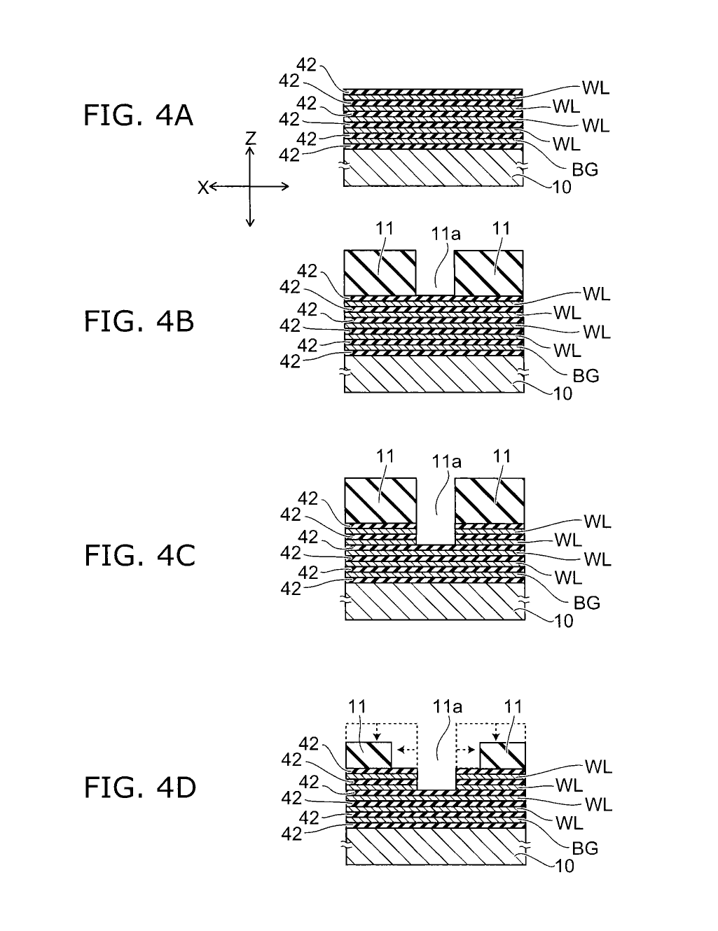

Next, a method for manufacturing a semiconductor device of the embodiment is described with reference to FIG. 4A to FIG. 6D, with priority given to a method for forming the staircase structure unit 50.

As shown in FIG. 4A, the back gate BG is formed on the substrate 10 via the insulating layer 42. On the back gate BG, the insulating layer 42 and the electrode layer WL are alternately stacked, and a stacked body including a plurality of insulating layers 42 and a plurality of electrode layers WL is formed. The number of electrode layers WL shown in the drawing is an example, and the number of electrode layers WL is not limited to that illustrated. The back gate BG, the insulating layer 42, and the electrode layer WL are formed by, for example, the CVD (chemical vapor deposition) method.

In the stacked body including the back gate BG, the plurality of insulating layers 42, and the plurality of electrode layers WL, the memory cell array 1 shown in FIG. 2 is formed for the memory cell array region. That is, after the U-shaped memory hole MH described above is formed in the stacked body mentioned above, the memory film 30 is formed on the inner wall (the side wall and the bottom wall) of the memory hole MH, and the channel body 20 is formed on the inside of the memory film 30.

The staircase structure unit 50 is formed in a region of the stacked body mentioned above on the outside in the X direction of the memory cell array 1. A method for forming the staircase structure unit 50 will now be described.

First, a resist film 11 shown in FIG. 4B is formed on the stacked body mentioned above, and exposure and development are performed on the resist film 11 to form an opening (or a slit) 11a in the resist film 11.

Then, the resist film 11 is used as a mask to perform, for example, the RIE (reactive ion etching) method to etch the stacked body. As shown in FIG. 4C, the top two insulating layers 42 and the top two electrode layers WL in the portion under the opening 11a are selectively removed by the etching.

Next, ashing processing using an oxygen-containing gas, for example, is performed on the resist film 11. Thereby, as shown in FIG. 4D, the resist film 11 is isotropically etched in the thickness direction and the plane direction, and the width in the X direction of the opening 11a is widened.

The resist film 11 with the width of the opening 11a widened is used as a mask to further perform RIE on the stacked body. Also at this time, layers in the portion exposed at the opening 11a are selectively removed in groups of the top two insulating layers 42 and the top two electrode layers WL.

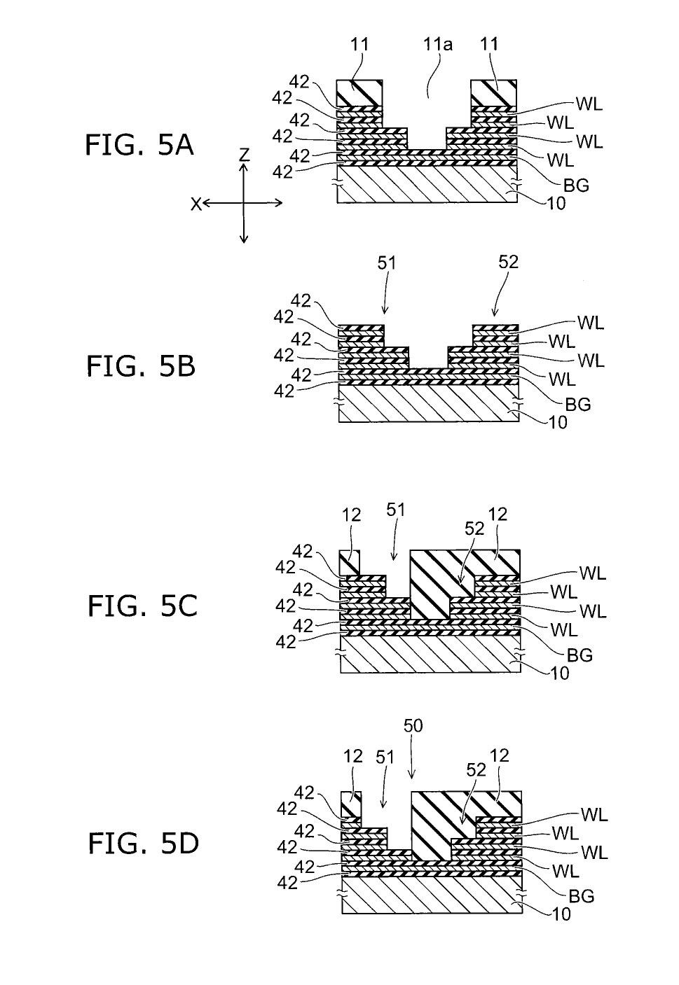

Thereby, as shown in FIG. 5A, the stacked body is fashioned into a staircase configuration. Then, the resist film 11 is removed by, for example, ashing processing using an oxygen-containing gas (FIG. 5B). By the staircase fashioning of the stacked body, the first staircase region 51 and the second staircase region 52 located to sandwich the deepest portion in the X direction are formed. At this point, the stairs are formed symmetrically to sandwich the deepest portion of the staircase structure unit in the X direction.

That is, both in the first staircase region 51 and in the second staircase region 52, layers have sunk from the uppermost stair toward the deepest portion in groups of four layers including two insulating layers 42 and two electrode layers WL. Each stair of the first staircase region 51 includes two insulating layers 42 and two electrode layers WL, and also each stair of the second staircase region 52 includes two insulating layers 42 and two electrode layers WL.

Next, of the first staircase region 51 and the second staircase region 52, the staircase region on the memory cell array 1 side is covered with a resist film. In FIG. 5C, for example, the second staircase region 52 is covered with a resist film 12. The resist film 12 covers also the deepest portion of the staircase structure unit. The resist film 12 is formed also on a portion of the first staircase region 51 where it is not intended to etch the stacked body.

Then, the resist film 12 is used as a mask to perform, for example, the RIE method to etch the stacked body. At this time, layers are etched in groups of one insulating layer 42 and one electrode layer WL. That is, the upper insulating layer 42 and the upper electrode layer WL in each stair of the first staircase region 51 are removed.

Thereby, as shown in FIG. 5D, in the first staircase region 51, the electrode layer WL in an odd position (the first or the third) on the upper side from the back gate BG forms the uppermost electrode layer in each stair. On the other hand, in the second staircase region 52, the electrode layer WL in an even position (the second or the fourth) on the upper side from the back gate BG forms the uppermost electrode layer in each stair.

After that, the resist film 12 is removed by, for example, ashing processing using an oxygen-containing gas (FIG. 6A). By the above processes, the staircase structure unit 50 in which the heights of the stairs from the deepest portion are asymmetrical across the deepest portion is formed.

The insulating layer 42 directly on the back gate BG forms the bottom of the deepest portion of the staircase structure unit 50. The height (the height from the deepest portion) of the first stair of the second staircase region 52 is higher than the height of the first stair of the first staircase region 51. The height of the second stair of the first staircase region 51 is higher than the height of the first stair of the second staircase region 52. The height of the second stair of the second staircase region 52 is higher than the height of the second stair of the first staircase region 51.

After the staircase structure unit 50 is formed, as shown in FIG. 6B, the interlayer insulating film 71 is deposited on the staircase structure unit 50 via the etching stop film 72. The upper surface of the interlayer insulating film 71 is made flat.

As the material of the interlayer insulating film 71, for example, silicon oxide may be used. As the material of the etching stop film 72, a different material from the interlayer insulating film 71, for example silicon nitride, may be used.

After the interlayer insulating film 71 is formed, as shown in FIG. 6C, a via hole 73 that reaches the back gate BG under the deepest portion of the staircase structure unit 50 and a plurality of via holes 73 that reach the uppermost electrode layers WL in the stairs are formed.

Each via hole 73 pierces the interlayer insulating film 71, the etching stop film 72 thereunder, and the insulating layer 42 thereunder and reaches the back gate BG or the electrode layer WL. The back gate BG or the uppermost electrode layer WL of each stair is exposed at the bottom of each via hole 73.

The plurality of via holes 73 are formed simultaneously and collectively by, for example, the RIE method using a not-shown resist film as a mask.

After that, the vias 75a to 75e are buried in the via holes 73 as shown in FIG. 6D.

The via 75a extends on the deepest portion of the staircase structure unit 50, and the lower end of the via 75a is connected to the back gate BG.

The via 75b and the via 75d are provided in the first staircase region 51. The via 75b is connected to the first electrode layer WL on the upper side from the back gate BG, and the via 75d is connected to the third electrode layer WL on the upper side from the back gate BG.

The via 75c and the via 75e are provided in the second staircase region 52. The via 75c is connected to the second electrode layer WL on the upper side from the back gate BG, and the via 75e is connected to the fourth electrode layer WL on the upper side from the back gate BG.

### Comparative Example

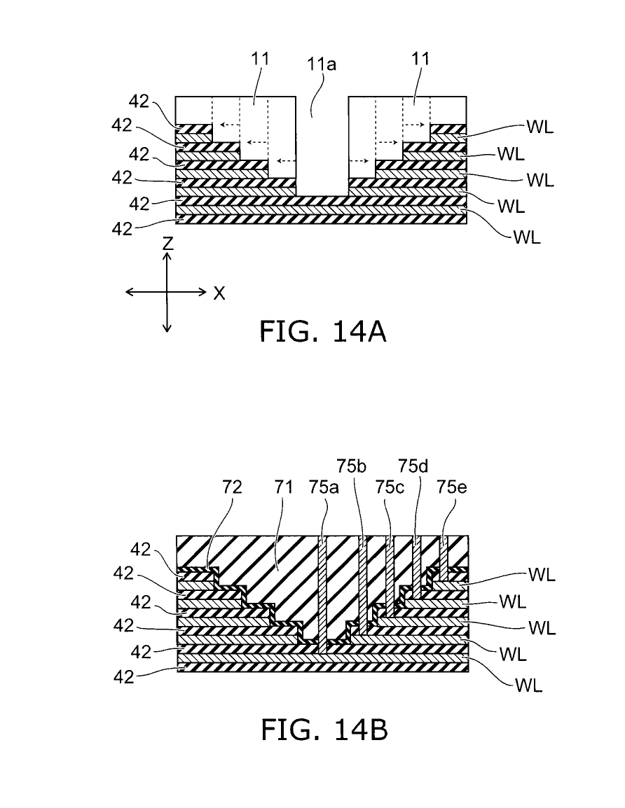

Here, a method for forming a staircase structure unit of a comparative example is described with reference to FIGS. 14A and 14B.

In the comparative example, the etching (RIE) of a stacked body using the resist film 11 as a mask and the process of isotropically etching the resist film 11 to expand the opening 11a are repeated.

First, the resist film 11 shown by the solid line in FIG. 14A is used as a mask to etch the stacked body. At this time, the highest insulating layer 42 and the highest electrode layer WL in the portion exposed at the opening 11a are removed by the etching.

Next, as shown by the broken line, the width in the X direction of the opening 11a is widened, and etching is performed to likewise remove layers in groups of the highest insulating layer 42 and the highest electrode layer WL in the portion exposed at the opening 11a.

After that, similarly, the process of widening the width of the opening 11a and the process of etching layers in groups of one insulating layer 42 and one electrode layer WL are repeated. Thereby, the stacked body is fashioned into a staircase configuration.

After that, as shown in FIG. 14B, the interlayer insulating film 71 is formed on the staircase structure unit via the etching stop film 72, and the vias 75a to 75e that reach the electrode layers WL of the stairs are formed.

In the comparative example, staircase structures that are symmetrical in the X direction across the deepest portion of the staircase structure unit are formed. That is, stairs with the same height including the electrode layer WL on the same story are formed in the two staircase regions sandwiching the deepest portion in the X direction. It is sufficient to provide the vias 75a to 75e only in one of the two staircase regions (in FIG. 14B, the staircase region on the right side), and the other staircase region results in a wasted region in which no via is provided.

In contrast, in the embodiment, as shown in FIG. 6D, the heights of the stairs are asymmetrical between the first staircase region 51 and the second staircase region 52 located to sandwich the deepest portion of the staircase structure unit 50 in the X direction. The first staircase region 51 and the second staircase region 52 do not include stairs of the intermediate electrode layer WL on the same story as each other, and the vias 75a to 75e are provided to be allocated to the first staircase region 51 and the second staircase region 52.

Therefore, no ineffective stair is produced in which no via is provided, and the staircase structure unit 50 can be effectively used. Consequently, the increase in the area where the staircase structure unit 50 is provided can be suppressed, and eventually the chip area (chip size) can be reduced.

By the embodiment, the same five vias 75a to 75e as the comparative example can be formed in an area with a planar size equal to the region on the right side of the deepest portion of the staircase structure unit of the comparative example shown in FIG. 14B. That is, the size of the staircase structure formation region in the embodiment can be suppressed to half the area of the staircase structure of the comparative example shown in FIG. 14B.

In the case of forming the same number of vias, the method of the embodiment can reduce the planar size of the resist film (slimming) and can reduce the number of processes of widening the opening width as compared to the method of the comparative example.

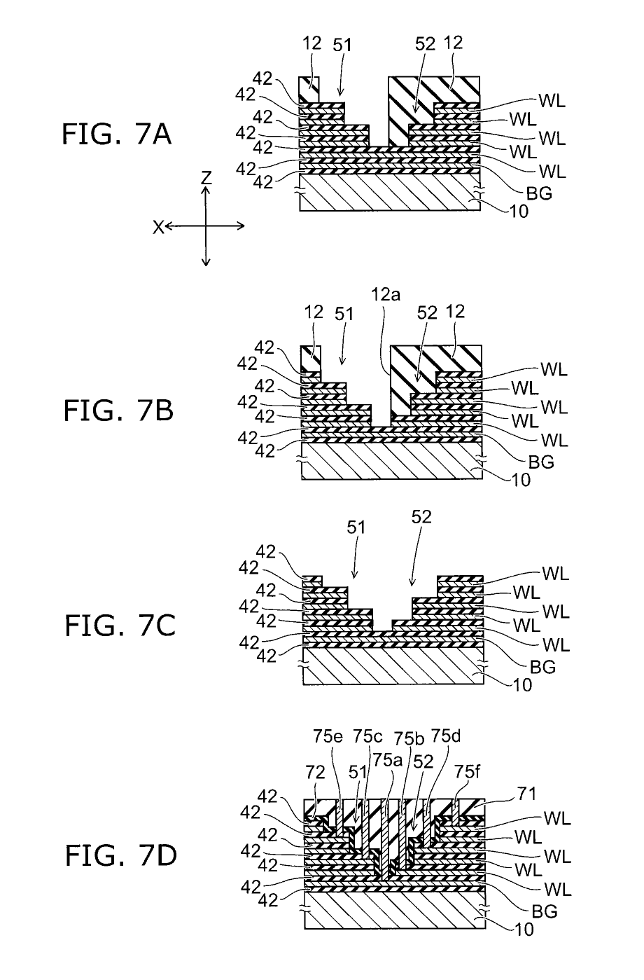

In the embodiment described above, in the process in which one of the first staircase region 51 and the second staircase region 52 is covered with the resist film 12, the entire surface of the deepest portion of the staircase structure unit is covered with the resist film 12 as shown in FIG. 5C. However, part of the deepest portion may not be covered with the resist film 12, and may be exposed as shown in FIG. 7A.

In FIG. 7A, the second staircase region 52 is covered with the resist film 12 similarly to FIG. 5C. In the deepest portion, the surface on the second staircase region 52 side is covered with the resist film 12, and the surface on the first staircase region 51 side is exposed.

Then, the resist film 12 is used as a mask to perform etching to remove layers in groups of one insulating layer 42 and one electrode layer WL in the portion not covered with the resist film 12 (FIG. 7B). At this time, also one insulating layer 42 and one electrode layer WL between a side wall 12a of the resist film 12 on the first staircase region 51 side and the first staircase region 51 are etched and removed. Thus, the number of stairs can be made larger by one than in the structure shown in FIG. 5D.

After that, the resist film 12 is removed by, for example, ashing processing (FIG. 7C), and then the interlayer insulating film 71 is formed on the staircase structure unit via the etching stop film 72 as shown in FIG. 7D. Further, vias 75b to 75f that reach the electrode layers WL of the stairs and the via 75a that reaches the back gate BG of the deepest portion are formed.

In the structure of FIG. 7D, the number of stairs is larger by one than in the structure of FIG. 6D. Thus, the structure of FIG. 7D includes the six vias 75a to 75f, which are larger in number by one than in the structure of FIG. 6D. The number of stairs can be increased by shifting the position of the side wall 12a in the patterning of the resist film 12, and an increase in the number of processes is not caused.

The staircase structure unit shown in FIG. 7D includes a stair array in which stairs of a plurality of conductive layers are aligned in a line in the X direction in a staircase configuration. Next to the back gate BG, which is the deepest portion of the stair array, in the X direction, a stair of the lowest electrode layer WL having a level difference of one stair with the back gate BG is provided.

Next to the lowest electrode layer WL in the X direction, the third lowest electrode layer WL with a level difference of two stairs with the lowest electrode layer WL is provided.

Next to the third lowest electrode layer WL in the X direction, the fifth lowest electrode layer WL having a level difference of two stairs with the third lowest electrode layer WL is provided.

Next to the back gate BG in the X direction, the second lowest electrode layer WL having a level difference of two stairs with the back gate BG is provided.

Next to the second lowest electrode layer WL in the X direction, the fourth lowest electrode layer WL having a level difference of two stairs with the second lowest electrode layer WL is provided.

Also in the structure of FIG. 7D, the heights of the stairs are asymmetrical between the first staircase region 51 and the second staircase region 52 sandwiching the deepest portion of the staircase structure unit in the X direction. The vias 75b and 75d reaching the intermediate electrode layers WL in odd positions (the first and the third) on the upper side from the back gate BG are provided in the second staircase region 52, and the vias 75c and 75e reaching the intermediate electrode layers WL in even positions (the second and the fourth) on the upper side from the back gate BG are provided in the first staircase region 51.

The first staircase region 51 and the second staircase region 52 do not include stairs of the intermediate electrode layer WL on the same story as each other, and the vias 75b to 75f are provided to be allocated to the first staircase region 51 and the second staircase region 52. Therefore, no ineffective stair is produced in which no via is provided. Thus, the increase in the area where the staircase structure unit is provided can be suppressed, and eventually the chip area (chip size) can be reduced.

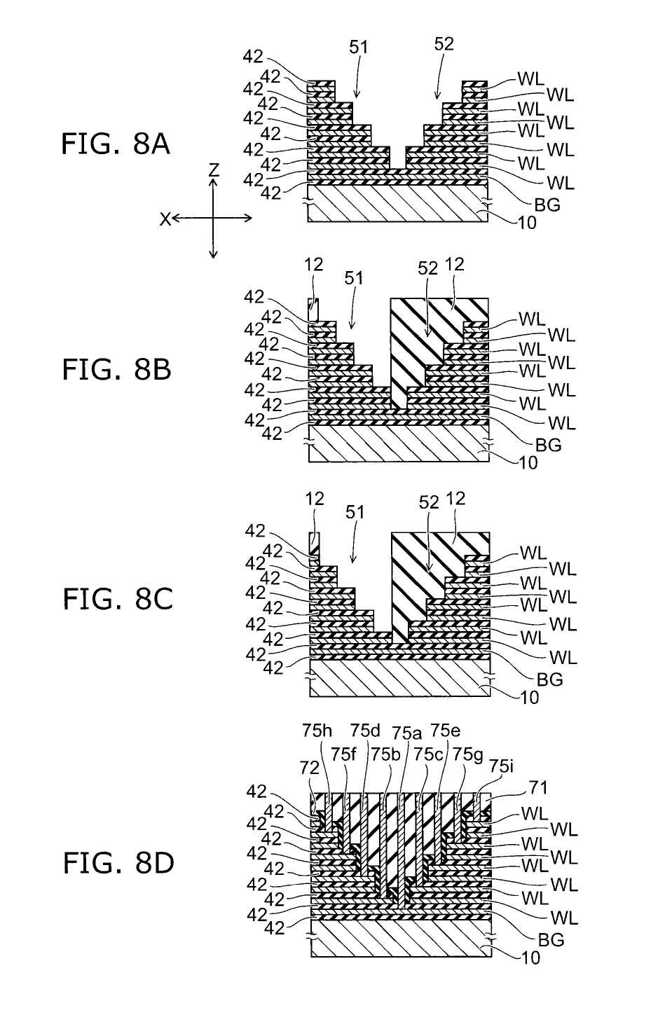

FIGS. 8A to 8D are schematic cross-sectional views showing a method for forming a staircase structure unit in the case where the number of electrode layers WL is larger than in the embodiment mentioned above. The drawings correspond to the processes of FIG. 5B and thereafter in the embodiment mentioned above.

Regardless of the number of electrode layers WL, first, similarly to the embodiment mentioned above, the first staircase region 51 and the second staircase region 52 in which each stair includes two electrode layers WL are formed symmetrically to sandwich the deepest portion in the X direction, as shown in FIG. 8A.

After that, as shown in FIG. 8B, one staircase region (e.g. the second staircase region 52) is covered with the resist film 12, and layers are etched and removed in groups of one insulating layer 42 and one electrode layer WL in the other staircase region (e.g. the first staircase region 51) (FIG. 8C).

After that, the resist film 12 is removed by, for example, ashing processing, and then as shown in FIG. 8D, the interlayer insulating film 71 is formed on the staircase structure unit via the etching stop film 72. Further, vias 75b to 75i that reach the electrode layers WL of the stairs and the via 75a that reaches the back gate BG of the deepest portion are formed.

The staircase structure unit shown in FIG. 8D includes a stair array in which stairs of a plurality of conductive layers are aligned in a line in the X direction in a staircase configuration. Next to the back gate BG, which is the deepest portion of the stair array, in the X direction, a stair of the lowest electrode layer WL having a level difference of one stair with the back gate BG is provided.

Next to the lowest electrode layer WL in the X direction, the third lowest electrode layer WL having a level difference of two stairs with the lowest electrode layer WL is provided.

Next to the third lowest electrode layer WL in the X direction, the fifth lowest electrode layer WL having a level difference of two stairs with the third lowest electrode layer WL is provided.

Next to the fifth lowest electrode layer WL in the X direction, the seventh lowest electrode layer WL having a level difference of two stairs with the fifth lowest electrode layer WL is provided.

Next to the back gate BG in the X direction, the second lowest electrode layer WL having a level difference of two stairs with the back gate BG is provided.

Next to the second lowest electrode layer WL in the X direction, the fourth lowest electrode layer WL having a level difference of two stairs with the second lowest electrode layer WL is provided.

Next to the fourth lowest electrode layer WL in the X direction, the sixth lowest electrode layer WL having a level difference of two stairs with the fourth lowest electrode layer WL is provided.

Next to the sixth lowest electrode layer WL in the X direction, the eighth lowest electrode layer WL having a level difference of two stairs with the sixth lowest electrode layer WL is provided.

Also in the structure of FIG. 8D, the heights of the stairs are asymmetrical between the first staircase region 51 and the second staircase region 52 sandwiching the deepest portion of the staircase structure unit in the X direction. The vias 75b, 75d, 75f, and 75h reaching the intermediate electrode layers WL in odd positions (the first, the third, the fifth, and the seventh) on the upper side from the back gate BG are provided in the first staircase region 51, and the vias 75c, 75e, and 75g reaching the intermediate electrode layers WL in even positions (the second, the fourth, and the sixth) on the upper side from the back gate BG are provided in the second staircase region 52.

The first staircase region 51 and the second staircase region 52 do not include stairs of the intermediate electrode layer WL on the same story as each other, and the vias 75b to 75i are provided to be allocated to the first staircase region 51 and the second staircase region 52. Therefore, no ineffective stair is produced in which no via is provided. Thus, the increase in the area where the staircase structure unit is provided can be suppressed, and eventually the chip area (chip size) can be reduced.

### Second Embodiment

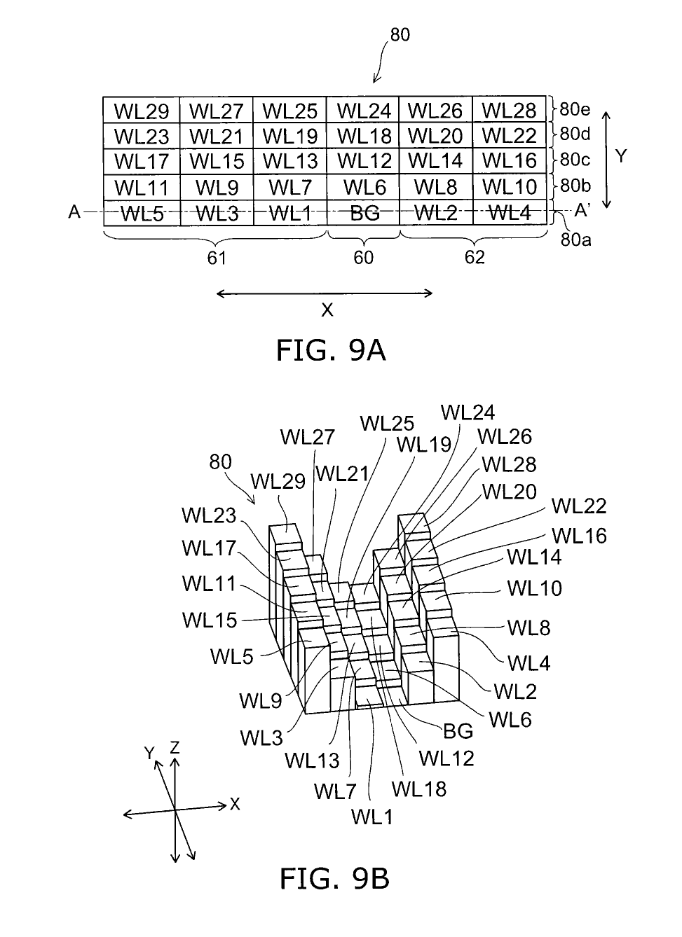

Next, FIG. 9A is a schematic plan view of a staircase structure unit 80 of a second embodiment, and FIG. 9B is a schematic perspective view of the staircase structure unit 80.

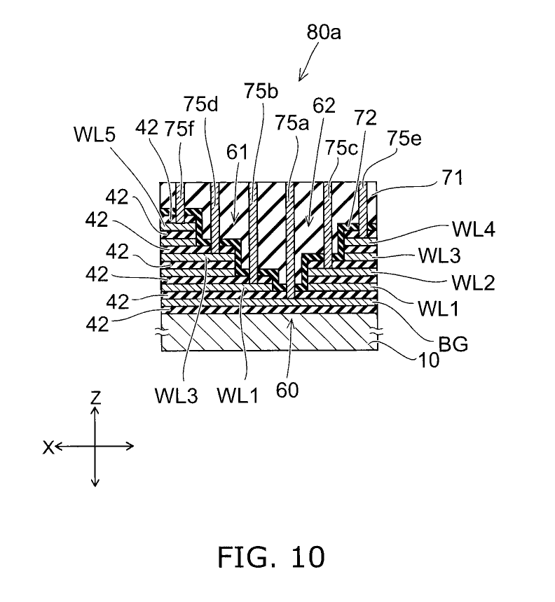

FIG. 10 shows the A-A′ cross section in FIG. 9A.

In FIGS. 9A and 9B, the conductive layer (the back gate BG and electrode layers WL1 to WL29) to be connected to the via in each stair is shown at the uppermost surface.

In the second embodiment, part of the stacked body including the back gate BG and a plurality of electrode layers WL1 to WL29 is fashioned in a staircase configuration not only in the X direction but also in the Y direction, and a staircase structure unit 80 is formed. The Y direction crosses the X direction, and is orthogonal to the X direction, for example.

The numbers added to the right of “WL” of the electrode layers WL1 to WL29 indicate where they are located in the order of electrode layers WL on the upper side from the back gate BG. In the following description, the electrode layers WL1 to WL29 may not be distinguished, and may be referred to as simply the electrode layer WL.

The back gate BG is provided on the substrate 10 via the insulating layer 42. The insulating layer 42 and the electrode layer WL are alternately stacked in plural on the back gate BG.

The plurality of electrode layers WL and the plurality of insulating layers 42 are fashioned in a staircase configuration along the X direction. The plurality of electrode layers WL and the plurality of insulating layers 42 are fashioned in a staircase configuration also along the Y direction. The staircase structure unit 80 includes a plurality of stair arrays 80a to 80e. Each of the stair arrays 80a to 80e includes a plurality of stairs aligned in a line in the X direction in a staircase configuration. The plurality of stair arrays 80a to 80e are arranged in a staircase configuration in the Y direction.

On the staircase structure unit 80, the interlayer insulating film 71 is provided via the etching stop film 72 similarly to the embodiment described above.

The upper surfaces of the stairs in the staircase structure unit 80 are partitioned in a matrix configuration in a planar view when the staircase structure unit 80 is viewed from the uppermost layer side, and a plurality of vias are provided on the stairs (some vias 75a to 75f are shown in FIG. 10). Each of the plurality of vias pierces the interlayer insulating film 71, the etching stop film 72, and the insulating layer 42 and reaches the uppermost electrode layer WL in each stair. The vias reach the electrode layers WL on stories different from one another.

For example, in FIG. 10, the via 75b is connected to the first electrode layer WL1 on the upper side from the back gate BG. The via 75c is connected to the second electrode layer WL2 on the upper side from the back gate BG. The via 75d is connected to the third electrode layer WL3 on the upper side from the back gate BG. The via 75e is connected to the fourth electrode layer WL4 on the upper side from the back gate BG. The via 75f is connected to the fifth electrode layer WL5 on the upper side from the back gate BG. The via 75a is connected to the back gate BG.

Next to the back gate BG, which is the deepest portion of the stair array 80a, in the X direction, a stair of the electrode layer WL1 having a level difference of one stair with the back gate BG is provided.

Next to the electrode layer WL1 in the X direction, the electrode layer WL3 having a level difference of two stairs with the electrode layer WL1 is provided.

Next to the electrode layer WL3 in the X direction, the electrode layer WL5 having a level difference of two stairs with the electrode layer WL3 is provided.

Next to the back gate BG in the X direction, the electrode layer WL2 having a level difference of two stairs with the back gate BG is provided.

Next to the electrode layer WL2 in the X direction, the electrode layer WL4 having a level difference of two stairs with the electrode layer WL2 is provided.

Next to the electrode layer WL6, which is the deepest portion of the stair array 80b, in the X direction, a stair of the electrode layer WL7 having a level difference of one stair with the electrode layer WL6 is provided.

Next to the electrode layer WL7 in the X direction, the electrode layer WL9 having a level difference of two stairs with the electrode layer WL7 is provided.

Next to the electrode layer WL9 in the X direction, the electrode layer WL11 having a level difference of two stairs with the electrode layer WL9 is provided.

Next to the electrode layer WL6 in the X direction, the electrode layer WL8 having a level difference of two stairs with the electrode layer WL6 is provided.

Next to the electrode layer WL8 in the X direction, the electrode layer WL10 having a level difference of two stairs with the electrode layer WL8 is provided.

Next to the electrode layer WL12, which is the deepest portion of the stair array 80c, in the X direction, a stair of the electrode layer WL13 having a level difference of one stair with the electrode layer WL12 is provided.

Next to the electrode layer WL13 in the X direction, the electrode layer WL15 having a level difference of two stairs with the electrode layer WL13 is provided.

Next to the electrode layer WL15 in the X direction, the electrode layer WL17 having a level difference of two stairs with the electrode layer WL15 is provided.

Next to the electrode layer WL12 in the X direction, the electrode layer WL14 having a level difference of two stairs with the electrode layer WL12 is provided.

Next to the electrode layer WL14 in the X direction, the electrode layer WL16 having a level difference of two stairs with the electrode layer WL14 is provided.

Next to the electrode layer WL18, which is the deepest portion of the stair array 80d, in the X direction, a stair of the electrode layer WL19 having a level difference of one stair with the electrode layer WL18 is provided.

Next to the electrode layer WL19 in the X direction, the electrode layer WL21 having a level difference of two stairs with the electrode layer WL19 is provided.

Next to the electrode layer WL21 in the X direction, the electrode layer WL23 having a level difference of two stairs with the electrode layer WL21 is provided.

Next to the electrode layer WL18 in the X direction, the electrode layer WL20 having a level difference of two stairs with the electrode layer WL18 is provided.

Next to the electrode layer WL20 in the X direction, the electrode layer WL22 having a level difference of two stairs with the electrode layer WL20 is provided.

Next to the electrode layer WL24, which is the deepest portion of the stair array 80e, in the X direction, a stair of the electrode layer WL25 having a level difference of one stair with the electrode layer WL24 is provided.

Next to the electrode layer WL25 in the X direction, the electrode layer WL27 having a level difference of two stairs with the electrode layer WL25 is provided.

Next to the electrode layer WL27 in the X direction, the electrode layer WL29 having a level difference of two stairs with the electrode layer WL27 is provided.

Next to the electrode layer WL24 in the X direction, the electrode layer WL26 having a level difference of two stairs with the electrode layer WL24 is provided.

Next to the electrode layer WL26 in the X direction, the electrode layer WL28 having a level difference of two stairs with the electrode layer WL26 is provided.

Each of the stair arrays 80a to 80e of the staircase structure unit 80 includes a first staircase region 61 and a second staircase region 62 provided to sandwich, in the X direction, the deepest portion 60 out of the plurality of stairs aligned in the X direction.

In the stair array 80a in which a stair for contact with the electrode layer WL5, a stair for contact with the electrode layer WL3, a stair for contact with the electrode layer WL1, a stair for contact with the back gate BG, a stair for contact with the electrode layer WL2, and a stair for contact with the electrode layer WL4 are aligned in the X direction, the deepest portion 60 is the stair for contact with the back gate BG.

In the stair array 80b in which a stair for contact with the electrode layer WL11, a stair for contact with the electrode layer WL9, a stair for contact with the electrode layer WL7, a stair for contact with the electrode layer WL6, a stair for contact with the electrode layer WL8, and a stair for contact with the electrode layer WL10 are aligned in the X direction, the deepest portion 60 is the stair for contact with the electrode layer WL6.

In the stair array 80c in which a stair for contact with the electrode layer WL17, a stair for contact with the electrode layer WL15, a stair for contact with the electrode layer WL13, a stair for contact with the electrode layer WL12, a stair for contact with the electrode layer WL14, and a stair for contact with the electrode layer WL16 are aligned in the X direction, the deepest portion 60 is the stair for contact with the electrode layer WL12.

In the stair array 80d in which a stair for contact with the electrode layer WL23, a stair for contact with the electrode layer WL21, a stair for contact with the electrode layer WL19, a stair for contact with the electrode layer WL18, a stair for contact with the electrode layer WL20, and a stair for contact with the electrode layer WL22 are aligned in the X direction, the deepest portion 60 is the stair for contact with the electrode layer WL18.

In the stair array 80e in which a stair for contact with the electrode layer WL29, a stair for contact with the electrode layer WL27, a stair for contact with the electrode layer WL25, a stair for contact with the electrode layer WL24, a stair for contact with the electrode layer WL26, and a stair for contact with the electrode layer WL28 are aligned in the X direction, the deepest portion 60 is the stair for contact with the electrode layer WL24.

In the cross-sectional structure of the stair array 80a shown in FIG. 10, the four electrode layers (intermediate electrode layers) WL1 to WL4, for example, are formed between the back gate BG and the uppermost electrode layer WL5.

Of the vias 75b, 75c, 75d, and 75e reaching the intermediate electrode layers WL1 to WL4, respectively, the vias 75b and 75d reaching the intermediate electrode layers WL1 and WL3 in odd positions (the first and the third) on the upper side from the back gate BG are provided in the first staircase region 61, and the vias 75c and 75e reaching the intermediate electrode layers WL2 and WL4 in even positions (the second and the fourth) on the upper side from the back gate BG are provided in the second staircase region 62.

Also in the stair array 80b in which a stair for contact with the electrode layer WL11, a stair for contact with the electrode layer WL9, a stair for contact with the electrode layer WL7, a stair for contact with the electrode layer WL6, a stair for contact with the electrode layer WL8, and a stair for contact with the electrode layer WL10 are aligned in the X direction, of the vias reaching the intermediate electrode layers WL7 to WL10, the vias reaching the intermediate electrode layers WL7 and WL9 in odd positions (the first and the third) on the upper side from the electrode layer WL6 of the deepest portion 60 are provided in the first staircase region 61, and the vias reaching the intermediate electrode layers WL8 and WL10 in even positions (the second and the fourth) on the upper side from the electrode layer WL6 are provided in the second staircase region 62.

Also in the stair array 80c in which a stair for contact with the electrode layer WL17, a stair for contact with the electrode layer WL15, a stair for contact with the electrode layer WL13, a stair for contact with the electrode layer WL12, a stair for contact with the electrode layer WL14, and a stair for contact with the electrode layer WL16 are aligned in the X direction, of the vias reaching the intermediate electrode layers WL13 to WL16, the vias reaching the intermediate electrode layers WL13 and WL15 in odd positions (the first and the third) on the upper side from the electrode layer WL12 of the deepest portion 60 are provided in the first staircase region 61, and the vias reaching the intermediate electrode layers WL14 and WL16 in even positions (the second and the fourth) on the upper side from the electrode layer WL12 are provided in the second staircase region 62.

Also in the stair array 80d in which a stair for contact with the electrode layer WL23, a stair for contact with the electrode layer WL21, a stair for contact with the electrode layer WL19, a stair for contact with the electrode layer WL18, a stair for contact with the electrode layer WL20, and a stair for contact with the electrode layer WL22 are aligned in the X direction, of the vias reaching the intermediate electrode layers WL19 to WL22, the vias reaching the intermediate electrode layers WL19 and WL21 in odd positions (the first and the third) on the upper side from the electrode layer WL18 of the deepest portion 60 are provided in the first staircase region 61, and the vias reaching the intermediate electrode layers WL20 and WL22 in even positions (the second and the fourth) on the upper side from the electrode layer WL18 are provided in the second staircase region 62.

Also in the stair array 80e in which a stair for contact with the electrode layer WL29, a stair for contact with the electrode layer WL27, a stair for contact with the electrode layer WL25, a stair for contact with the electrode layer WL24, a stair for contact with the electrode layer WL26, and a stair for contact with the electrode layer WL28 are aligned in the X direction, of the vias reaching the intermediate electrode layers WL25 to WL28, the vias reaching the intermediate electrode layers WL25 and WL27 in odd positions (the first and the third) on the upper side from the electrode layer WL24 of the deepest portion 60 are provided in the first staircase region 61, and the vias reaching the intermediate electrode layers WL26 and WL28 in even positions (the second and the fourth) on the upper side from the electrode layer WL24 are provided in the second staircase region 62.

That is, in each of the stair arrays 80a to 80e, the first staircase region 61 and the second staircase region 62 located to sandwich the deepest portion 60 in the X direction do not include stairs of the intermediate electrode layer WL on the same story as each other, and vias are provided to be allocated to the first staircase region 61 and the second staircase region 62. Therefore, no ineffective stair is produced in which no via is provided, and the staircase structure unit 80 can be effectively used. Consequently, the increase in the area where the staircase structure unit 80 is provided can be suppressed, and eventually the chip area (chip size) can be reduced.

Furthermore, in the second embodiment, a staircase structure is formed also in the Y direction. Therefore, the size in the X direction can be suppressed as compared to the case where 29 stairs are formed in the X direction.

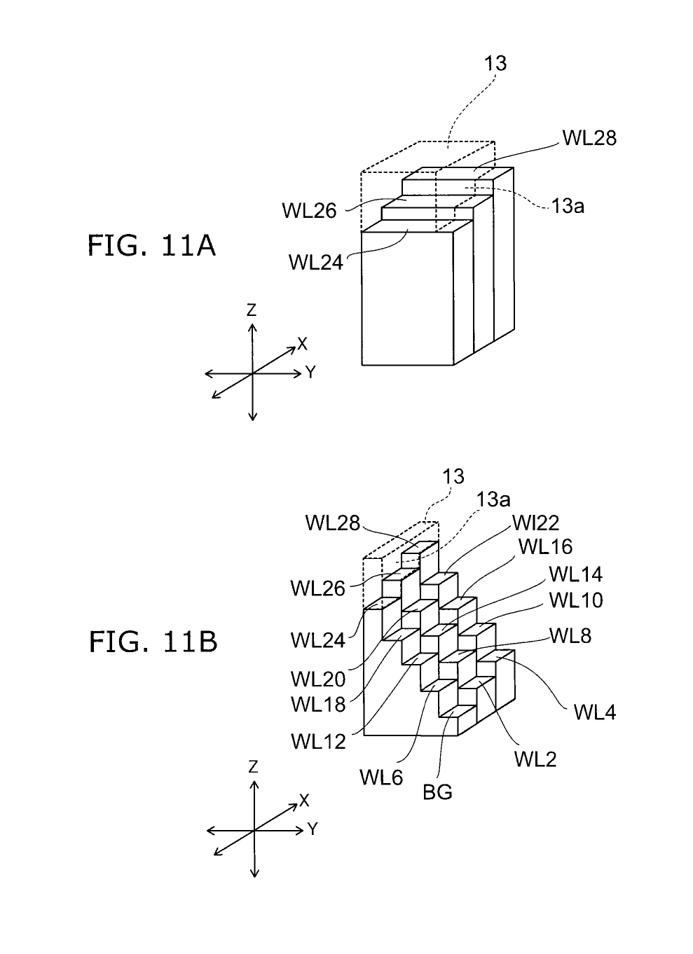

Next, a method for forming the staircase structure unit 80 of the second embodiment is described with reference to FIGS. 11A and 11B.

FIGS. 11A and 11B show only the deepest portion 60 and the second staircase region 62 in the staircase structure unit 80.

First, similarly to the first embodiment, fashioning for a staircase structure along the X direction is performed. After that, a resist film 13 shown by the broken line in FIG. 11A is formed on the staircase structure.

Then, the resist film 13 is used as a mask to etch (RIE) and remove layers in groups of one insulating layer 42 and one electrode layer WL in the portion exposed from the resist film 13. The top one insulating layer 42 and the top one electrode layer WL of each of the stairs formed in a staircase configuration along the X direction are etched.

After that, the resist film 13 is slimmed in the Y direction to widen the width in the Y direction of the portion exposed from the resist film 13 of the stacked body. In FIG. 11A, a side wall 13a of the resist film 13 on the right side, for example, is recessed to the left.

Then, the slimmed resist film 13 is used as a mask to etch (RIE) and remove layers in groups of one insulating layer 42 and one electrode layer WL in the portion exposed from the resist film 13.

The sliming of the resist film 13 and the etching of the insulating layer 42 and the electrode layer WL described above are repeated, and a staircase structure is formed also in the Y direction as shown in FIG. 11B.

The number of electrode layers WL1 to WL29 in the second embodiment is an example, and the number of electrode layers WL is not limited thereto. Also the number of stairs in the X direction and the number of stairs in the Y direction in the staircase structure unit 80 are not limited to those illustrated.

### Third Embodiment

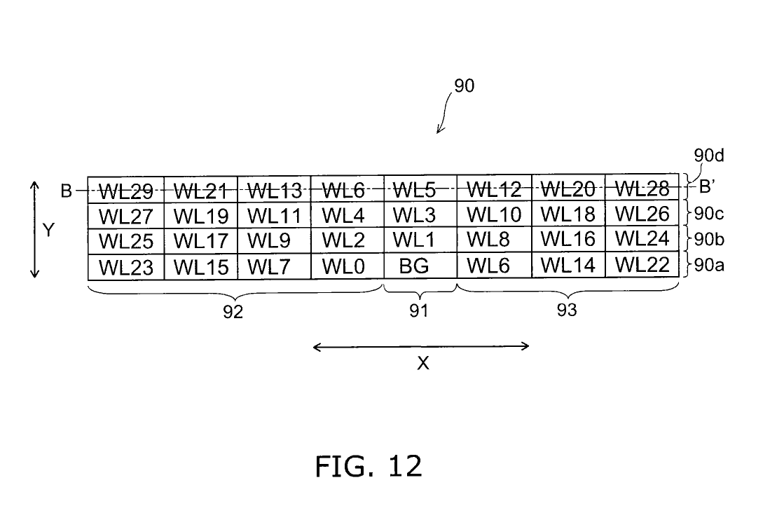

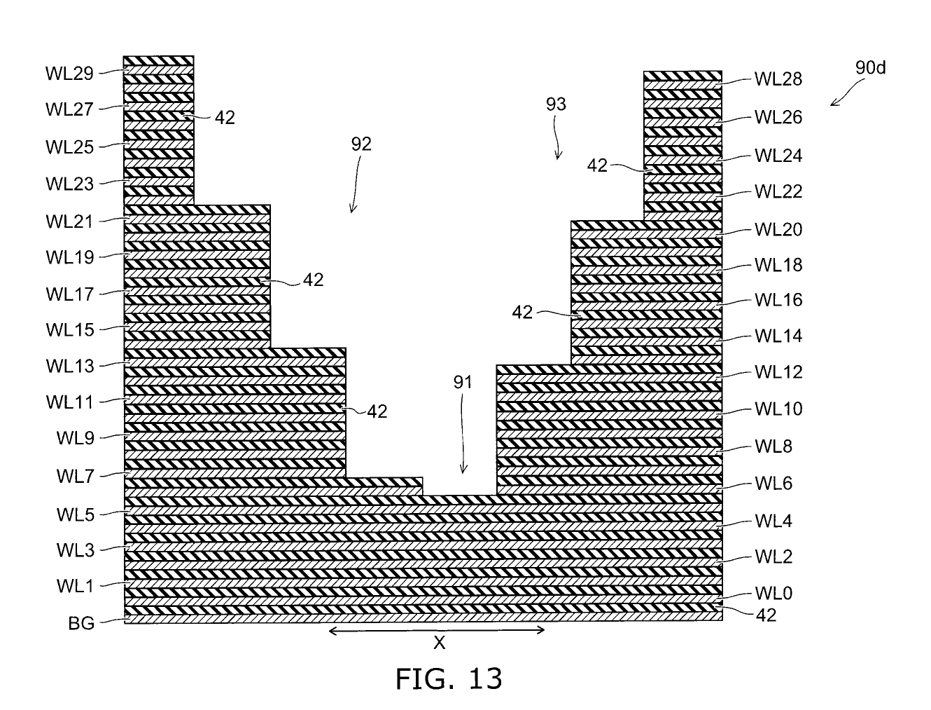

Next, FIG. 12 is a schematic plan view of a staircase structure unit 90 of a third embodiment, and FIG. 13 is a cross-sectional view taken along line B-B′ in FIG. 12.

In FIG. 12, the conductive layer (the back gate BG and electrode layers WL0 to WL29) to be connected to the via in each stair is shown at the uppermost surface.

Also in the third embodiment, similarly to the second embodiment, part of the stacked body including the back gate BG and a plurality of electrode layers WL0 to WL29 is fashioned in a staircase configuration not only in the X direction but also in the Y direction, and a staircase structure unit 90 is formed.

In the third embodiment, the first electrode layer on the upper side from the back gate BG is expressed as the electrode layer WL0. The electrode layer WL0 is provided on the back gate BG via the insulating layer 42. The plurality of electrode layers WL1 to WL29 are stacked on the electrode layer WL0. The numbers added to the right of “WL” of the electrode layers WL1 to WL29 indicate where they are located in the order of electrode layers WL on the upper side from the electrode layer WL0. In the following description, the electrode layers WL0 to WL29 may not be distinguished, and may be referred to as simply the electrode layer WL. The insulating layer 42 is provided between electrode layers WL.

The plurality of electrode layers WL and the plurality of insulating layers 42 are fashioned in a staircase configuration along the X direction. The plurality of electrode layers WL and the plurality of insulating layers 42 are fashioned in a staircase configuration also along the Y direction. The staircase structure unit 90 includes a plurality of stair arrays 90a to 90d. Each of the stair arrays 90a to 90d includes a plurality of stairs aligned in a line in the X direction in a staircase configuration. The plurality of stair arrays 90a to 90d are arranged in a staircase configuration in the Y direction.

Also on the staircase structure unit 90, the interlayer insulating film 71 is provided via the etching stop film 72 similarly to the embodiments described above.

Also in the third embodiment, similarly to the second embodiment, the upper surfaces of the stairs in the staircase structure unit 90 are partitioned in a matrix configuration in a planar view when the staircase structure unit 90 is viewed from the uppermost layer side, and a plurality of vias are provided on the stairs. Each of the plurality of vias pierces the interlayer insulating film 71, the etching stop film 72, and the insulating layer 42 and reaches the uppermost electrode layer WL of each stair. The vias reach the electrode layers WL on stories different from one another.

Next to the back gate BG, which is the deepest portion of the stair array 90a, in the X direction, a stair of the electrode layer WL0 having a level difference of one stair with the back gate BG is provided.

Next to the electrode layer WL0 in the X direction, the electrode layer WL7 having a level difference of seven stairs with the electrode layer WL0 is provided.

Next to the electrode layer WL7 in the X direction, the electrode layer WL15 having a level difference of eight stairs with the electrode layer WL7 is provided.

Next to the electrode layer WL15 in the X direction, the electrode layer WL23 having a level difference of eight stairs with the electrode layer WL15 is provided.

Next to the back gate BG in the X direction, the electrode layer WL6 having a level difference of seven stairs with the back gate BG is provided.

Next to the electrode layer WL6 in the X direction, the electrode layer WL14 having a level difference of eight stairs with the electrode layer WL6 is provided.

Next to the electrode layer WL14 in the X direction, the electrode layer WL22 having a level difference of eight stairs with the electrode layer WL14 is provided.

Next to the electrode layer WL1, which is the deepest portion of the stair array 90b, in the X direction, a stair of the electrode layer WL2 having a level difference of one stair with the electrode layer WL1 is provided.

Next to the electrode layer WL2 in the X direction, the electrode layer WL9 having a level difference of seven stairs with the electrode layer WL2 is provided.

Next to the electrode layer WL9 in the X direction, the electrode layer WL17 having a level difference of eight stairs with the electrode layer WL9 is provided.

Next to the electrode layer WL17 in the X direction, the electrode layer WL25 having a level difference of eight stairs with the electrode layer WL17 is provided.

Next to the electrode layer WL1 in the X direction, the electrode layer WL8 having a level difference of seven stairs with the electrode layer WL1 is provided.

Next to the electrode layer WL8 in the X direction, the electrode layer WL16 having a level difference of eight stairs with the electrode layer WL8 is provided.

Next to the electrode layer WL16 in the X direction, the electrode layer WL24 having a level difference of eight stairs with the electrode layer WL16 is provided.

Next to the electrode layer WL3, which is the deepest portion of the stair array 90c, in the X direction, a stair of the electrode layer WL4 having a level difference of one stair with the electrode layer WL3 is provided.

Next to the electrode layer WL4 in the X direction, the electrode layer WL11 having a level difference of seven stairs with the electrode layer WL4 is provided.

Next to the electrode layer WL11 in the X direction, the electrode layer WL19 having a level difference of eight stairs with the electrode layer WL11 is provided.

Next to the electrode layer WL19 in the X direction, the electrode layer WL27 having a level difference of eight stairs with the electrode layer WL19 is provided.

Next to the electrode layer WL3 in the X direction, the electrode layer WL10 having a level difference of seven stairs with the electrode layer WL3 is provided.

Next to the electrode layer WL10 in the X direction, the electrode layer WL18 having a level difference of eight stairs with the electrode layer WL10 is provided.

Next to the electrode layer WL18 in the X direction, the electrode layer WL26 having a level difference of eight stairs with the electrode layer WL18 is provided.

Next to the electrode layer WL5, which is the deepest portion of the stair array 90d, in the X direction, a stair of the electrode layer WL6 having a level difference of one stair with the electrode layer WL5 is provided.

Next to the electrode layer WL6 in the X direction, the electrode layer WL13 having a level difference of seven stairs with the electrode layer WL6 is provided.

Next to the electrode layer WL13 in the X direction, the electrode layer WL21 having a level difference of eight stairs with the electrode layer WL13 is provided.

Next to the electrode layer WL21 in the X direction, the electrode layer WL29 having a level difference of eight stairs with the electrode layer WL21 is provided.

Next to the electrode layer WL5 in the X direction, the electrode layer WL12 having a level difference of seven stairs with the electrode layer WL5 is provided.

Next to the electrode layer WL12 in the X direction, the electrode layer WL20 having a level difference of eight stairs with the electrode layer WL12 is provided.

Next to the electrode layer WL20 in the X direction, the electrode layer WL28 having a level difference of eight stairs with the electrode layer WL20 is provided.

Each of the stair arrays 90a to 90d of the staircase structure unit 90 includes a first staircase region 92 and a second staircase region 93 provided to sandwich, in the X direction, the deepest portion 91 out of the plurality of stairs aligned in the X direction.

The deepest portion 91 of the stair array 90a is a stair for contact with the back gate BG. The deepest portion 91 of the stair array 90b is a stair for contact with the electrode layer WL1. The deepest portion 91 of the stair array 90c is a stair for contact with the electrode layer WL3. The deepest portion 91 of the stair array 90d is a stair for contact with the electrode layer WL5.

The stair array 90a does not include stairs on the same story, and the vias reaching the electrode layers WL on stories different from one another are allocated to the first staircase region 92 and the second staircase region 93 located to sandwich the deepest portion 91 (the back gate BG) in the X direction.

Also the stair array 90b does not include stairs on the same story, and the vias reaching the electrode layers WL on stories different from one another are allocated to the first staircase region 92 and the second staircase region 93 located to sandwich the deepest portion 91 (the electrode layer WL1) in the X direction.

Also the stair array 90c does not include stairs on the same story, and the vias reaching the electrode layers WL on stories different from one another are allocated to the first staircase region 92 and the second staircase region 93 located to sandwich the deepest portion 91 (the electrode layer WL3) in the X direction.

Also the stair array 90d does not include stairs on the same story, and the vias reaching the electrode layers WL on stories different from one another are allocated to the first staircase region 92 and the second staircase region 93 located to sandwich the deepest portion 91 (the electrode layer WL5) in the X direction.

Therefore, also in the third embodiment, no ineffective stair is produced in which no via is provided, and the staircase structure unit 90 can be effectively used. Consequently, the increase in the area where the staircase structure unit 90 is provided can be suppressed, and eventually the chip area (chip size) can be reduced.

Furthermore, also in the third embodiment, a staircase structure is formed also in the Y direction similarly to the second embodiment. Therefore, the size in the X direction can be suppressed as compared to the case where 30 stairs are formed in the X direction.

Next, a method for forming the staircase structure unit 90 of the third embodiment is described.

Similarly to the second embodiment, first, fashioning for a staircase structure along the X direction is performed. FIG. 13 shows this state. A staircase structure in which the heights are asymmetrical in the X direction across the deepest portion 91 is formed.

In the state after the staircase fashioning along the X direction, the deepest portion 91 is a stair including the electrode layer WL5 as the uppermost electrode layer. The first staircase region 92 includes a stair including the electrode layer WL29 as the uppermost electrode layer, a stair including the electrode layer WL21 as the uppermost electrode layer, a stair including the electrode layer WL13 as the uppermost electrode layer, and a stair including the electrode layer WL6 as the uppermost electrode layer. The second staircase region 93 includes a stair including the electrode layer WL28 as the uppermost electrode layer, a stair including the electrode layer WL20 as the uppermost electrode layer, and a stair including the electrode layer WL12 as the uppermost electrode layer.

Then, a resist film (not shown) formed on the staircase structure is used as a mask to etch (RIE) and remove layers in groups of two insulating layers 42 and two electrode layers WL in the portion exposed from the resist film. The top two insulating layers 42 and the top two electrode layers WL of each of the stairs formed in a staircase configuration in the X direction are etched.

After the etching, the resist film is slimmed in the Y direction to widen the width in the Y direction of the portion exposed from the resist film of the stacked body. Then, the slimmed resist film is used as a mask to etch (RIE) and remove layers in groups of two insulating layers 42 and two electrode layers WL in the portion exposed from the resist film.

The sliming of the resist film, the etching in groups of two insulating layers 42, and the etching in groups of two electrode layers WL described above are repeated, and a staircase structure is formed also in the Y direction.

Staircase fashioning in the Y direction is described as follows with reference to FIG. 12. After staircase fashioning in the X direction is performed, in a state where the region where the stair arrays 90b to 90d will be formed is covered with a resist film and the region where the stair array 90a will be formed is exposed from the resist film, first, layers are etched and removed in groups of two insulating layers 42 and two electrode layers WL.

Next, the resist film is slimmed in the Y direction, and also the region where the stair array 90b will be formed is exposed from the resist film. In this state, layers in the region exposed from the resist film where the stair array 90a will be formed and the region exposed from the resist film where the stair array 90b will be formed are etched and removed in groups of two insulating layers 42 and two electrode layers WL.

Next, the resist film is further slimmed in the Y direction, and also the region where the stair array 90c will be formed is exposed from the resist film. In this state, layers in the region exposed from the resist film where the stair array 90a will be formed, the region exposed from the resist film where the stair array 90b will be formed, and the region exposed from the resist film where the stair array 90c will be formed are etched and removed in groups of two insulating layers 42 and two electrode layers WL.

By the etching performed three times using the resist film mentioned above, in the region where the stair array 90a will be formed, layers are removed in groups of the top six electrode layers WL and the top six insulating layers 42; and a stair including the electrode layer WL23 as the uppermost electrode layer, a stair including the electrode layer WL15 as the uppermost electrode layer, a stair including the electrode layer WL7 as the uppermost electrode layer, a stair including the electrode layer WL0 as the uppermost electrode layer, a stair including the back gate BG as the uppermost electrode layer (the deepest portion), a stair including the electrode layer WL6 as the uppermost electrode layer, a stair including the electrode layer WL14 as the uppermost electrode layer, and a stair including the electrode layer WL22 as the uppermost electrode layer are formed.

By the etching performed three times using the resist film mentioned above, in the region where the stair array 90b will be formed, layers are removed in groups of the top four electrode layers WL and the top four insulating layers 42; and a stair including the electrode layer WL25 as the uppermost electrode layer, a stair including the electrode layer WL17 as the uppermost electrode layer, a stair including the electrode layer WL9 as the uppermost electrode layer, a stair including the electrode layer WL2 as the uppermost electrode layer, a stair including the electrode layer WL1 as the uppermost electrode layer (the deepest portion), a stair including the electrode layer WL8 as the uppermost electrode layer, a stair including the electrode layer WL16 as the uppermost electrode layer, and a stair including the electrode layer WL24 as the uppermost electrode layer are formed.

By the etching performed three times using the resist film mentioned above, in the region where the stair array 90c will be formed, layers are removed in groups of the top two electrode layers WL and the top two insulating layers 42; and a stair including the electrode layer WL27 as the uppermost electrode layer, a stair including the electrode layer WL19 as the uppermost electrode layer, a stair including the electrode layer WL11 as the uppermost electrode layer, a stair including the electrode layer WL4 as the uppermost electrode layer, a stair including the electrode layer WL3 as the uppermost electrode layer (the deepest portion), a stair including the electrode layer WL10 as the uppermost electrode layer, a stair including the electrode layer WL18 as the uppermost electrode layer, and a stair including the electrode layer WL26 as the uppermost electrode layer are formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a stacked body including a plurality of conductive layers and a plurality of insulating layers each provided between the conductive layers, the stacked body including a staircase structure unit including a stair array including stairs of the conductive layers aligned in a line in a first direction in a staircase configuration; and
a plurality of vias provided individually above the stairs and individually reaching the conductive layers,
the stair array including:
a deepest portion;
one stair provided next to the deepest portion in the first direction and having a level difference of one step to the deepest portion; and
a plurality of stairs each having a level difference of a plurality of steps to a stair next in the first direction.

2. The device according to claim 1, wherein
the conductive layers are provided in a staircase configuration both in the first direction and in a second direction crossing the first direction,
the staircase structure unit includes a plurality of the stair array,
the stair arrays are arranged in a staircase configuration in the second direction, and
each of the vias is provided on each stair partitioned in a matrix configuration in a planar view viewed from an uppermost layer side and reaches the uppermost conductive layer of each stair.

3. The device according to claim 1, further comprising:
a channel body provided in a hole piercing the stacked body; and
a memory film provided between the channel body and a side wall of the hole and including a charge storage film.

4. The device according to claim 3, wherein the staircase structure unit is provided in a region on an outside in the first direction of a region in which the channel body and the memory film are provided.

5. The device according to claim 1, wherein
the staircase structure unit includes a first staircase region and a second staircase region provided to sandwich the deepest portion in the first direction and
the vias are provided to be allocated to the first staircase region and the second staircase region.

6. The device according to claim 5, wherein the first staircase region does not include a stair with a same height as a stair in the second staircase region.

7. The device according to claim 2, wherein a plurality of stairs arranged in the second direction do not include stairs with a same height in the second direction.

8. The device according to claim 7, wherein each of the stairs arranged in the second direction has a level difference of a plurality of stairs with a stair next in the second direction.

9. The device according to claim 1, wherein the conductive layer is a silicon layer doped with an impurity.

10. The device according to claim 3, wherein the channel body is a silicon film.

11. The device according to claim 1, wherein an interlayer insulating film is provided on the staircase structure unit and the via extends through the interlayer insulating film toward the conductive layer of each of the stairs.

12. A method for manufacturing a semiconductor device comprising:
forming a first staircase region and a second staircase region in a stacked body, the stacked body including a plurality of conductive layers and a plurality of insulating layers each provided between the conductive layers, the first staircase region and the second staircase region being provided to sandwich a deepest portion in a first direction, each stair of the first staircase region and the second staircase region including two of the conductive layers; and
removing the upper conductive layer in each stair of one of the first staircase region and the second staircase region.

13. The method according to claim 12, further comprising processing the conductive layers into a staircase configuration also in a second direction crossing the first direction.

14. The method according to claim 12, further comprising forming an interlayer insulating film on the first staircase region and the second staircase region.

15. The method according to claim 14, further comprising:
forming a plurality of via holes piercing the interlayer insulating film and individually reaching the conductive layers of the stairs of the first staircase region and the second staircase region; and
forming a via in the via hole.

16. The method according to claim 15, wherein the via holes are formed simultaneously by an RIE (reactive ion etching) method.

17. The method according to claim 12, wherein the first staircase region and the second staircase region in which each stair includes two of the conductive layers are formed by repeating etching of the stacked body using a resist film as a mask and reducing a planar size of the resist film.

18. The method according to claim 17, wherein
the planar size of the resist film is reduced by isotropical etching and the stacked body is etched by an RIE method.

19. The method according to claim 12, wherein in a state where one of the first staircase region and the second staircase region is covered with a resist film, the upper conductive layer of each stair of another staircase region is removed by etching.

20. The method according to claim 12, further comprising:
forming a hole piercing the stacked body;
forming a memory film including a charge storage film on a side wall of the hole; and
forming a channel body on a side wall of the memory film.
